(19) United States
(12) Patent Application Publication
(10) Pub. No.: US 2018/0076169 A1
(43) Pub. Date: Mar. 15, 2018

(54) CHIP BONDING PROCESS

(71) Applicant: RODAN (TAIWAN) LTD., Taichung City (TW)

(72) Inventor: Kuo-Kuang CHANG, Taichung City (TW)

(21) Appl. No.: 15/335,722

(22) Filed: Oct. 27, 2016

(30) Foreign Application Priority Data
Sep. 13, 2016 (TW) 105129767

(51) Int. Cl. H01L 23/00; B23K 1/00; H01L 33/62

(52) U.S. Cl. CPC H01L 24/81; H01L 2924/37001; H01L 24/13; H01L 24/11; H01L 33/62; H01L 2224/81024; H01L 2224/8112; H01L 2224/81898; H01L 2224/13111; H01L 2224/13147; H01L 2224/13155; H01L 2224/13166; H01L 2224/13144; H01L 2224/13084; H01L 2224/1132; H01L 2224/11418; H01L 2924/12041; B23K 1/0016

(57) ABSTRACT

A chip bonding process is provided, including following steps of: providing a plurality of microchips, providing a substrate, applying a flux which is pasty, a first placement step, a first hot pressing step, a second placement step, a second hot pressing step and a third hot pressing step. The first and second placement steps are arranging the microchips on the substrate. The first and second hot pressing step is heating the flux to turn into liquid state and cooling the flux to make all of the microchips and the substrate positioned with each other. The third hot pressing step is melting all of the first electrode sets and all of the second electrode sets to connect with each other and cooling the flux to a room temperature.

### BACKGROUND OF THE INVENTION

### Field of the Invention

The present invention relates to a chip bonding process.

### Description of the Prior Art

A light-emitting diode (LED) has a preferable color saturation and has advantages like light-weighted, power-saving and longer service life, so businesses actively develop and use the light-emitting diode in many ways, for example, LED back light module, OLED and AMOLED display technology. However, as technology improves, current LED technology cannot satisfy application needs. Take the AMOLED display technology which is commonly used for example, the color that a screen using the AMOLED display technology displays is over-saturated and distorted, a user cannot view the screen under the sunlight, and the screen will have burn-in after a long-term use.

Therefore, the businesses need to develop new technologies to solve the existing problems, and one of the developing priorities is a micro light-emitting diode (Micro-LED). The micro-LED can be applied in 3C products, for example, a displayer, a display screen, a wearable device and a head-up display member (for example, Google Glass) or a VR device. However, the technology of the micro-LED is operated in minimum (micrometer) level, so manufacturing the micro-LED requires high precision and yield rate.

The present invention has arisen to mitigate and/or obviate the afore-described disadvantages.

### SUMMARY OF THE INVENTION

The major object of the present invention is to provide a chip bonding process which melts a flux and a metal plating layer respectively through repeated heating to effectively and stably position a chip unit on a base unit so as to elevate a bonding precision and stability and a manufacturing yield rate.

To achieve the above and other objects, a chip bonding process is provided, including following steps of: providing a plurality of microchips, each of the plurality of microchips having a first electrode set; providing a substrate and positioning the substrate on a chip-bonding machine, the substrate having a plurality of second electrode sets corresponding to the first electrode sets of the microchips respectively; applying a flux which is pasty between the first and second electrode sets; a first placement step, arranging a part of the first electrode sets of the microchips to correspond to part of the second electrode sets of the substrate according to a first arrangement mode, the flux connected to the part of the first electrode sets and the part of second electrode sets, wherein in the first arrangement mode, the part of the first electrode sets and the part of second electrode sets are arranged in intervals vertically and horizontally; a first hot pressing step, heating the flux in a first preset temperature to turn the flux into liquid state, and make the part of the first electrode sets and the part of the second electrode sets approach each other, then cooling the flux so that the flux position the part of the first electrode sets and the part of the second electrode sets; a second placement step, arranging another part of the first electrode sets of the microchips to correspond to another part of the second electrode sets of the substrate according to a second arrangement mode, the flux connected to the another part of the first electrode sets and the another part of the second electrode sets, wherein in the second arrangement mode, the another part of the first electrode sets and the another part of the second electrode sets are arranged in intervals vertically and horizontally, the first and second arrangement modes are matrixedly complementary; a second hot pressing step, heating the flux in the first preset temperature to turn the flux into liquid state and make the another part of the first electrode sets and the another part of the second electrode sets approach each other, then cooling the flux so that the flux position the another part of the first electrode sets and the another part of the second electrode sets; a third hot pressing step, heating and pressing all of the first and the second electrode sets in a second preset temperature to weld all of the first and the second electrode sets and cooling all of the first and the second electrode sets to a room temperature.

The present invention will become more obvious from the following description when taken in connection with the accompanying drawings, which show, for purpose of illustrations only, the preferred embodiment(s) in accordance with the present invention.

### BRIEF DESCRIPTION OF THE DRAWINGS

FIG. 1 is a flow chart of steps of an embodiment of the present invention;

FIG. 2 is a drawing showing a microchip being arranged on a substrate of the embodiment of the present invention;

FIG. 3 is a partially-enlarged view of a second electrode set of the embodiment of the present invention;

FIG. 4 is a partially-enlarged view of a metal plating layer of the embodiment of the present invention;

FIGS. 5 and 6 are drawings showing first and second placement steps of the embodiment of the present invention;

FIG. 7 is a drawing showing a hot-pressing process of the embodiment of the present invention; and

FIG. 8 is a partially-enlarged view of the metal plating layer of another embodiment of the present invention.

### DETAILED DESCRIPTION OF THE PREFERRED EMBODIMENTS

The present invention will be clearer from the following description when viewed together with the accompanying drawings, which show, for purpose of illustrations only, the preferred embodiment in accordance with the present invention.

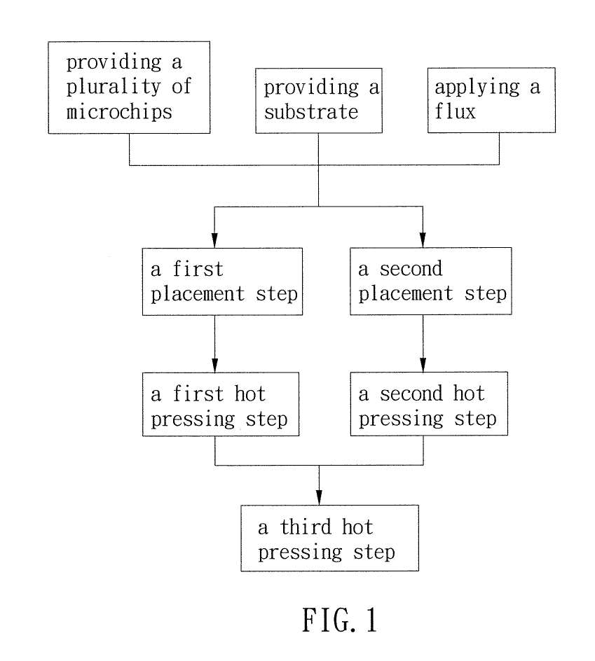

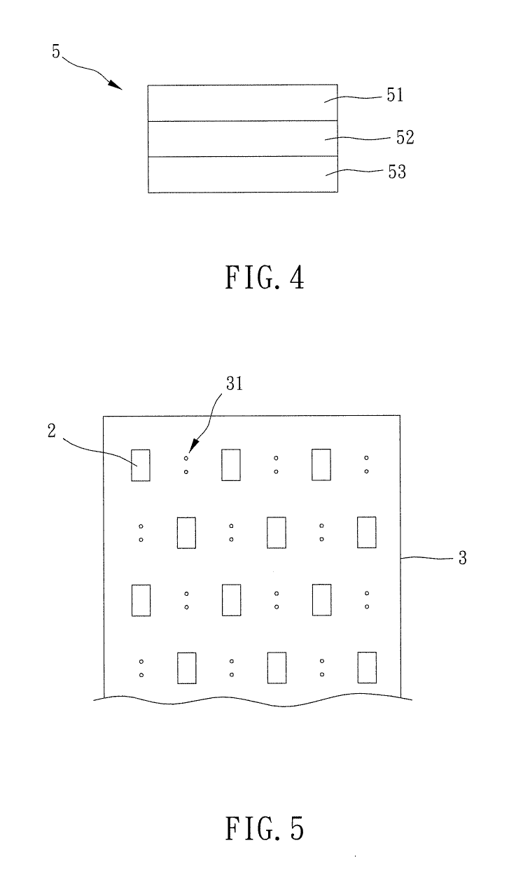

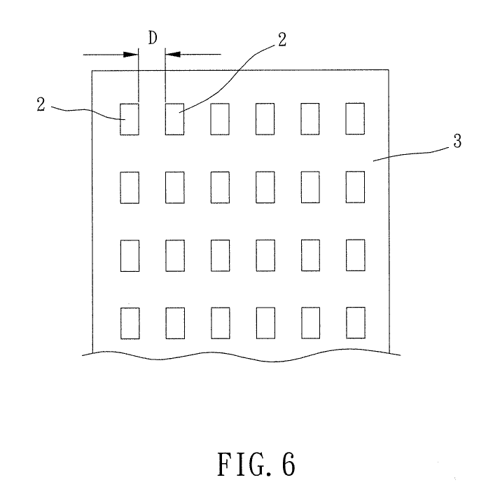

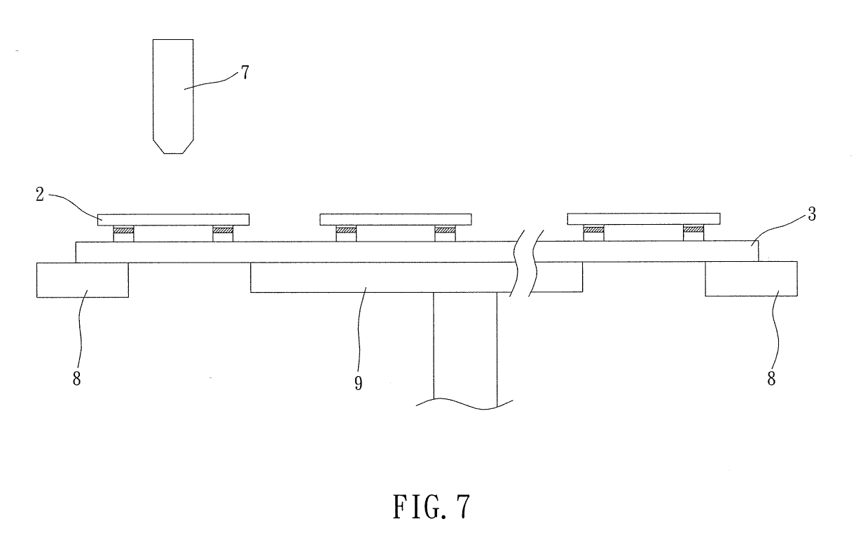

Please refer to FIGS. 1 to 5 for a preferred embodiment of the present invention. A chip bonding process, including following steps of: providing a plurality of microchips 2, each of the plurality of microchips 2 having a first electrode set 21; providing a substrate 3 and positioning the substrate 3 on a chip-bonding machine 1, the substrate 3 having a plurality of second electrode sets 31 corresponding to the first electrode sets 21 of the microchips 2 respectively; applying a flux 4 which is pasty between the first and second electrode sets 21, 31; a first placement step, arranging a part of the first electrode sets 21 of the microchips 2 to correspond to part of the second electrode sets 31 of the substrate 3 according to a first arrangement mode, the flux 4 connected to the part of the first electrode sets 21 and the part of second electrode sets 31, wherein in the first arrangement mode, the part of the first electrode sets 21 and the part of second electrode sets 31 are arranged in intervals vertically and horizontally; a first hot pressing step, heating the flux 4 in a first preset temperature to turn the flux 4 into liquid state, and make the part of the first electrode sets 21 and the part of the second electrode sets 31 approach each other, then cooling the flux 4 so that the flux 4 position the part of the first second electrode sets 21 and the part of the second electrode sets 31; a second placement step, arranging another part of the first electrode sets 21 of the microchips 2 to correspond to another part of the second electrode sets 31 of the substrate 3 according to a second arrangement mode, the flux 4 connected to the another part of the first electrode sets 21 and the another part of the second electrode sets 31, wherein in the second arrangement mode, the another part of the first electrode sets 21 and the another part of the second electrode sets 31 are arranged in intervals vertically and horizontally, the first and second arrangement modes are matrixedly complementary; a second hot pressing step, heating the flux 4 in the first preset temperature to turn the flux 4 into liquid state and make the another part of the first electrode sets 21 and the another part of the second electrode sets 31 approach each other, then cooling the flux 4 so that the flux 4 position the another part of the first electrode sets 21 and the another part of the second electrode sets 31; a third hot pressing step, heating and pressing all of the first and the second electrode sets 21, 31 in a second preset temperature to weld all of the first and the second electrode sets 21, 31 and cooling all of the first and the second electrode sets 21, 31 to a room temperature.

It is to be noted that because the microchip 2 is small, and in order to prevent the microchip 2 from being damaged due to too much clamping force; therefore, preferably, a suction nozzle 6 is used to move the microchip 2 to the substrate 2. Similarly, the microchip 2 may be pressed through a special pressurizing member 7, and a pressurizing pressure is 1 g to 100 g per 5 mil² (1˜100 g/5 mil²). The substrate 3 is one of a FR-4 substrate, a BT substrate, a glass, a prop, a ceramic, an aluminum substrate, a copper substrate, a silicon substrate, a flexible substrate (PI) and a sapphire.

The flux 4 is used to remove oxide or stains on surfaces of all of the first and second electrode sets 21, 31 to elevate a bonding quality, and the flux 4 can protect the surface to be wielded from being oxidized again. More importantly, the first and second hot pressing step are first chip-bonding (pre-position), and when the flux 4 cools down, the flux 4 transfers from liquid to solid and connects and fixes all of the first and second electrode sets 21, 31. In other words, each said microchip 2 is positioned on the substrate 3 via the flux 4. The first preset temperature is preferably set to be between 120° C. and 230° C. so that there is no thermal effect on other elements. That is, when choosing the flux 4, a melting point is preferably between 120° C. and 230° C. or lower than 120° C. so that the flux 4 can be heated and melted quickly to save energy and time.

More specifically, each of the second electrode sets 31 further includes a metal plating layer 5, and in the first and second hot pressing step, the flux 4 is melted to connect the first electrode set 21 and the metal plating layer 5. The metal plating layer 5 is formed through etching. Preferably, a top surface of the metal is plane and has more contact area which is smooth, so the metal plating layer 5 can be stably connected to the first electrode set 21.

More specifically, the metal plating layer 5 consists of a stannum layer 51, a copper layer 52 and a base layer 53 hierarchically from outside to inside, the base layer 53 is made of nickel or titanium, and the second preset temperature is greater than or equal to a melting point of the stannum layer 51. It is understandable that the third hot pressing step is melting the stannum layer 51 to connect the stannum layer 51 with the first electrode set 21, and when the stannum layer 51 cools down, the chip bonding process is accomplished, so the third hot pressing step may also called second chip-bonding. Similarly, to have a preferable time of temperature rising and save a processing cost, for example but not limited to, the second preset temperature is preferably between 230° C. to 330° C. In this embodiment, the first preset temperature is 180° C., and the second preset temperature is 260° C. so as to melt the stannum layer 51 completely; and the flux 4 is vaporized in the temperature state so as to produce a preferable product.

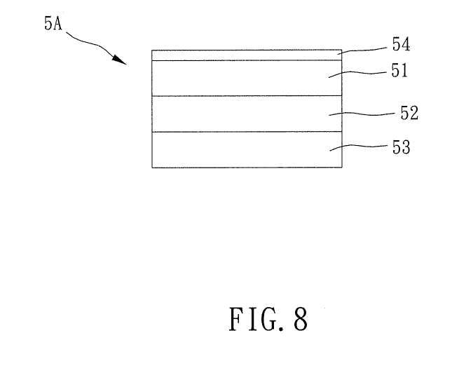

In addition, the metal plating layer 5 may be in other modes. Please refer to a metal plating layer 5A of another embodiment of FIG. 8, the metal plating layer 5A further has a gold layer 54, and the gold layer 54 covers the stannum layer 51. Specifically, a thickness of the gold layer 54 is 0.2 μm, so the gold layer 54 can prevent other metals from being oxidized and keep other metals in a preferable state before bonding.

Please further refer to the embodiment of FIGS. 1 to 5, a distance (D) between two said microchips 2 which are next to each other on a direction is smaller than 200 μm, and an area of each said microchip 2 is between 10 μm² and 300 μm². A dimension of each said microchip 2 and a gap between two said microchips 2 are small, so a yield rate may decrease due to slight changes. In addition, in this embodiment, an area of each said microchip 2 is smaller than 5 mil²; therefore, to ensure a manufacturing process having the high yield rate, the first and second electrode sets 21, 31 are connected with each other through two-step hot pressing.

Furthermore, the first and second electrode sets 21, 31 move toward each other to connect each other in two steps, every time that the first and second electrode sets 21, 31 approach each other, and a distance between the first and second electrode sets 21, 31 becomes smaller; therefore, the flux 4 and the stannum layer 51 which are melted will not splash when receiving force, and two said microchips 2 neighboring to each other are not easily electrically connected with each other unexpectedly to cause a short circuit so as to prevent from having adverse effects on the substrate 3 and other circuits or members. Preferably, the flux 4 may be a non-conductive and non-corrosive (for example, a rosin organic series) to prevent short circuit effectively and to provide a preferable bonding success rate. More preferably, a thickness of the stannum layer 51 is between 1 μm and 10 μm to ensure that when the stannum layer 51 is squeezed, the stannum layer 51 does not spill out from a gap between two said microchips 2. After multiple times of actual manufacturing process tests, the stannum layer 51 provides a preferable bonding quality when the thickness of the stannum layer 51 is between 5 μm to 7 μm.

In this embodiment, the flux 4 is put on the second electrode sets 31 on single point, so in addition to putting all of the flux 4 on the plurality of second electrode sets 31 in one time, the flux 4 may also be engaged with the plurality of second electrode sets 31 according to different requirements of the first or second arrangement modes. Of course, the flux 4 may be arranged in different ways. The flux 4 may be put on the second electrode sets 31 through screen printing or spray coating.

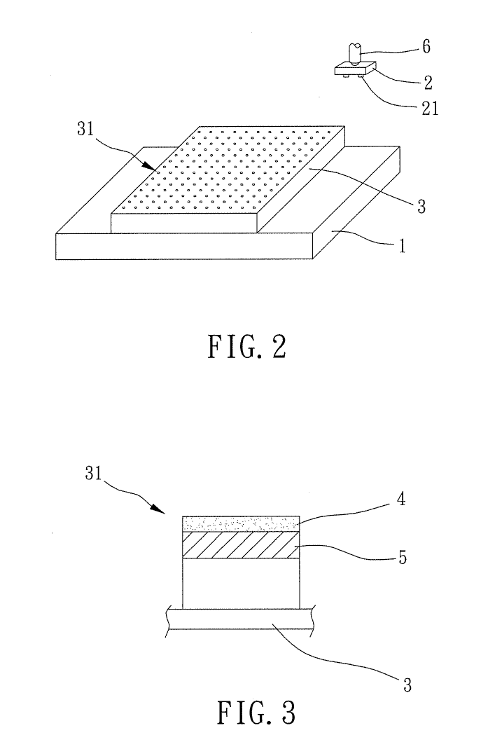

Please refer to FIG. 2, preferably, the chip bonding process further provides a track unit 8 and a heater 9, the track unit 8 has a heating position and a cooling position, the substrate 3 is movably arranged on the track unit 8 between the heating position and the cooling position, and the heater 9 is arranged on the heating position to heat the substrate 3. After being heated, the track unit 8 drives the substrate 3 and the plurality of microchips 2 to move to the cooling position to let the temperature cool down.

Given the above, in the chip bonding process, the flux or the stannum layer are melted in two steps through the first and second hot pressing steps to conduct the second chip-bonding to elevate a bonding stability between the microchip unit and the substrate. In addition, the flux and the stannum layer do not spill out from the gap therebetween easily so as to prevent two said microchips neighboring to each other from causing short circuit and to ensure the preferable bonding success rate (the yield rate). The flux can be put on the plurality of second electrode sets in a specific arrangement mode according various requirements so as to elevate the bonding success rate.

While we have shown and described various embodiments in accordance with the present invention, it should be clear to those skilled in the art that further embodiments may be made without departing from the scope of the present invention.

What is claimed is:

1. A chip bonding process, including following steps of:
providing a plurality of microchips, each of the plurality of microchips having a first electrode set;
providing a substrate and positioning the substrate on a chip-bonding machine, the substrate having a plurality of second electrode sets corresponding to the first electrode sets of the microchips respectively;
applying a flux which is pasty between the first and second electrode sets;
a first placement step, arranging a part of the first electrode sets of the microchips to correspond to part of the second electrode sets of the substrate according to a first arrangement mode, the flux connected to the part of the first electrode sets and the part of second electrode sets, wherein in the first arrangement mode, the part of the first electrode sets and the part of second electrode sets are arranged in intervals vertically and horizontally;
a first hot pressing step, heating the flux in a first preset temperature to turn the flux into liquid state and make the part of the first electrode sets and the part of the second electrode sets approach each other, then cooling the flux so that the flux position the part of the first electrode sets and the part of the second electrode sets;
a second placement step, arranging another part of the first electrode sets of the microchips to correspond to another part of the second electrode sets of the substrate according to a second arrangement mode, the flux connected to the another part of the first electrode sets and the another part of the second electrode sets, wherein in the second arrangement mode, the another part of the first electrode sets and the another part of the second electrode sets are arranged in intervals vertically and horizontally, the first and second arrangement modes are matrixedly complementary;
a second hot pressing step, heating the flux in the first preset temperature to turn the flux into liquid state and make the another part of the first electrode sets and the another part of the second electrode sets approach each other, then cooling the flux so that the flux position the another part of the first electrode sets and the another part of the second electrode sets;
a third hot pressing step, heating and pressing all of the first and the second electrode sets in a second preset temperature to weld all of the first and the second electrode sets and cooling all of the first and the second electrode sets to a room temperature.

2. The chip bonding process of claim 1, wherein the first preset temperature is between 120° C. to 230° C.

3. The chip bonding process of claim 1, wherein the second preset temperature is greater than 230° C. but not greater than 330° C.

4. The chip bonding process of claim 1, wherein each of the second electrode sets further includes a metal plating layer, in the first hot pressing step, the flux is welded to connect the part of the first electrode sets and the metal plating layer, the metal plating layer consists of a stannum layer, a copper layer and a base layer hierarchically from outside to inside, the base layer is made of nickel or titanium, and the second preset temperature is greater than or equal to a melting point of the stannum layer.

5. The chip bonding process of claim 4, wherein the metal plating layer further has a gold layer, and the gold layer covers the stannum layer.

6. The chip bonding process of claim 4, wherein a thickness of the stannum layer is between 1 μm and 10 μm.

7. The chip bonding process of claim 6, wherein a thickness of the stannum layer is between 5 μm and 7 μm.

8. The chip bonding process of claim 1, wherein a distance between two said microchips which are next to each other on a direction is smaller than 200 μm, and an area of each said microchip is between 10 μm² and 300 μm².

9. The chip bonding process of claim 1, wherein the flux is put on the second electrode sets through screen printing, single-point arrangement or spray coating.

10. The chip bonding process of claim 7, wherein a top surface of the metal plating layer is plane, and the first preset temperature is 180° C.; the second preset temperature is 260° C.; the substrate is one of a FR-4 substrate, a BT substrate, a glass, a prop, a ceramic, an aluminum substrate, a copper substrate, a silicon substrate, a flexible substrate (PI) and a sapphire; the flux is put on the second electrode sets through single-point arrangement, a distance between two said microchips which are next to each other on a direction is smaller than 200 μm, and an area of each said microchip is smaller than 5 mil²; the chip bonding process further provides a track unit and a heater, the track unit has a heating position and a cooling position, the substrate is movably arranged on the track unit between the heating position and the cooling position, and the heater is arranged on the heating position to heat the substrate; a pressing pressure is 1 g to 100 g per 5 mil² (1˜100 g/5 mil²).
